(19) United States
(12) Patent Application Publication
(10) Pub. No.: US 2025/0266385 A1
(43) Pub. Date: Aug. 21, 2025

(54) FILM ADHESIVE, DICING/DIE BONDING INTEGRATED FILM, AND SEMICONDUCTOR DEVICE AND METHOD FOR PRODUCING SAME

(71) Applicant: Resonac Corporation, Minato-ku, Tokyo (JP)

(72) Inventors: Takahiro KURODA, Minato-ku, Tokyo (JP); Junichi ICHIKAWA, Minato-ku, Tokyo (JP); Keita HOSONO, Minato-ku, Tokyo (JP); Takaaki NIWA, Minato-ku, Tokyo (JP)

(21) Appl. No.: 18/859,546

(22) PCT Filed: Mar. 14, 2024
(86) PCT No.: PCT/JP2024/010087

§ 371 Date: Oct. 24, 2024

(30) Foreign Application Priority Data
Mar. 15, 2023 (WO) PCT/JP2023/010166

(51) Int. Cl. H01L 23/00; C09J 7/10; C09J 11/04; C09J 163/00; H01L 23/538; H01L 25/065; H10B 80/00

(52) U.S. Cl. CPC H01L 24/29; C09J 7/10; C09J 11/04; C09J 163/00; H01L 23/538; H01L 24/32; H01L 24/83; H01L 25/0657; H10B 80/00; C09J 2203/326; C09J 2301/408; H01L 24/48; H01L 24/73; H01L 2224/29191; H01L 2224/32145; H01L 2224/32225; H01L 2224/48225; H01L 2224/73265; H01L 2224/83191; H01L 2224/83862; H01L 2225/0651; H01L 2225/06562; H01L 2924/1438

(57) ABSTRACT

A film-shaped adhesive contains a thermosetting resin component and an elastomer and may further contain an inorganic filler. The content of the elastomer is 18% by mass or more with respect to the total amount of the film-shaped adhesive. The content of the inorganic filler is 0 to 25% by mass with respect to the total amount of the film-shaped adhesive. A storage modulus at 150° C. of a cured product obtained when the film-shaped adhesive is cured under conditions of 140° C. and 30 minutes is 80 MPa or more. A thickness of the film-shaped adhesive is 15 μm or less.

### TECHNICAL FIELD

The present disclosure relates to a film-shaped adhesive, a dicing/die-bonding integrated film, and a semiconductor device and a method for producing the same.

### BACKGROUND ART

In recent years, a Stacked Multi Chip Package (MCP) in which semiconductor chips are stacked in multiple stages has become widespread, and is mounted as a memory semiconductor package or the like for a mobile phone or a mobile audio device. In addition, with multi-functionalization of mobile phones and the like, high-speed, high-density, high-integration, and the like of semiconductor packages are also promoted.

As a method for producing a semiconductor device, a method in which a dicing/die-bonding integrated film including an adhesive layer and a pressure-sensitive adhesive layer is stuck to a back surface of a semiconductor wafer, and then the semiconductor wafer, the adhesive layer, and the pressure-sensitive adhesive layer are partially cut and singulated (semiconductor wafer back surface sticking method) is generally used. For example, Patent Literatures 1 and 2 disclose a film-shaped adhesive used for an adhesive layer in such a method.

### CITATION LIST

### Patent Literature

Patent Literature 1: WO 2013/133275 A1
Patent Literature 2: WO 2020/013250 A1

### SUMMARY OF INVENTION

### Technical Problem

Meanwhile, in the stacked MCP, since semiconductor chips are stacked in multiple stages, a film-shaped adhesive used for a dicing/die-bonding integrated film is required to have a sufficient breaking strength even when a thin film (for example, with a thickness of 15 μm or less) is formed. When the film-shaped adhesive has a sufficient breaking strength, the processability (for example, film cutting properties for punching into a predetermined shape) when a thin film is formed tends to be excellent.

In addition, in recent semiconductor packages, in a semiconductor chip including a circuit layer and a semiconductor layer, the circuit layer tends to be thick and the semiconductor layer tends to be thin. In such a semiconductor package, for example, a chip crack may occur during wire bonding in which a circuit layer of a semiconductor chip and an electrode of a substrate are connected with a bonding wire. It is presumed that such a chip crack occurs by vibration during wire bonding because the semiconductor layer becomes thin and brittle. Therefore, a film-shaped adhesive used for a dicing/die-bonding integrated film is required to be able to prevent the occurrence of chip cracks.

Therefore, a main object of the present disclosure is to provide a film-shaped adhesive which has excellent processability when a thin film is formed and can prevent the occurrence of chip cracks.

### Solution to Problem

The present inventors have extensively conducted studies for achieving the above-mentioned object, and resultantly found that when the content of an elastomer in a film-shaped adhesive is set to a predetermined range or more, the content of an inorganic filler in the film-shaped adhesive is set to a predetermined range or less, and the storage modulus of the film-shaped adhesive after curing is set to a predetermined range or more, the processability at the time of forming a thin film can be improved, and further, the occurrence of chip cracks can be prevented, leading to completion of the invention of the present disclosure.

The present disclosure provides a film-shaped adhesive according to [1] to [8], a dicing/die-bonding integrated film according to [9], a semiconductor device according to [10] and [11], and a method for producing a semiconductor device according to [12] and [13].

[1]A film-shaped adhesive, containing: a thermosetting resin component; and an elastomer, and optionally further containing an inorganic filler, in which a content of the elastomer is 18% by mass or more with respect to a total amount of the film-shaped adhesive, and a content of the inorganic filler is 0 to 25% by mass with respect to the total amount of the film-shaped adhesive, a storage modulus at 150° C. of a cured product obtained when the film-shaped adhesive is cured at 140° C. for 30 minutes is 80 MPa or more, and a thickness of the film-shaped adhesive is 15 μm or less.

[2] The film-shaped adhesive according to [1], in which a content of the elastomer is 18 to 35% by mass with respect to the total amount of the film-shaped adhesive.

[3] The film-shaped adhesive according to [1] or [2], in which a content of the inorganic filler is 0 to 3% by mass with respect to the total amount of the film-shaped adhesive.

[4] The film-shaped adhesive according to any one of [1] to [3], in which a storage modulus at 30° C. of a cured product obtained when the film-shaped adhesive is cured under conditions of 140° C. and 30 minutes is 2,000 MPa or less.

[5] The film-shaped adhesive according to any one of [1] to [4], in which the thermosetting resin component contains an epoxy resin and a phenol resin.

[6] The film-shaped adhesive according to any one of [1] to [5], in which a glass transition temperature of the elastomer is 0 to 30° C.

[7] The film-shaped adhesive according to any one of [1] to [6], in which the film-shaped adhesive is used in a process for producing a semiconductor device formed by stacking a plurality of semiconductor chips.

[8] The film-shaped adhesive according to [7], in which the semiconductor device is a three-dimensional NAND memory.

[9]A dicing/die-bonding integrated film, including: a base material layer; a pressure-sensitive adhesive layer; and an adhesive layer made of the film-shaped adhesive according to any one of [1] to [6], in this order.

[10]A semiconductor device, including: a first semiconductor chip; a support member mounted with the first semiconductor chip; and a cured product of the film-shaped adhesive according to any one of [1] to [6], the cured product being provided between the first semiconductor chip and the support member and bonding the first semiconductor chip to the support member.

[11] The semiconductor device according to [10], further including a second semiconductor chip different from the first semiconductor chip, the second semiconductor chip being stacked on a surface of the first semiconductor chip.

[12]A method for producing a semiconductor device, the method including sticking the adhesive layer of the dicing/die-bonding integrated film according to [9] to a semiconductor wafer, preparing a plurality of singulated semiconductor chips with an adhesive piece by cutting the semiconductor wafer with the adhesive layer stuck thereto, and bonding, as the semiconductor chip with an adhesive piece, a first semiconductor chip with an adhesive piece having a first semiconductor chip and a first adhesive piece to a support member via the adhesive piece.

[13] The method for producing a semiconductor device according to [12], further including bonding, as the semiconductor chip with an adhesive piece, a second semiconductor chip with an adhesive piece having a second semiconductor chip and a second adhesive piece to a surface of the first semiconductor chip in the first semiconductor chip with an adhesive piece bonded to the support member via the second adhesive piece.

### Advantageous Effects of Invention

According to the present disclosure, a film-shaped adhesive which has excellent processability when a thin film is formed and can prevent the occurrence of chip cracks is provided. The film-shaped adhesive of some aspects can also prevent warpage of a semiconductor device (semiconductor package). Further, according to the present disclosure, a dicing/die-bonding integrated film, and a semiconductor device and a method for producing the same, in each of which such a film-shaped adhesive is used, are provided. Further, according to the present disclosure, a method for producing a semiconductor device using such a dicing/die-bonding integrated film is provided.

### BRIEF DESCRIPTION OF DRAWINGS

FIG. 1 is a schematic cross-sectional view showing one embodiment of a film-shaped adhesive.

FIG. 2 is a schematic cross-sectional view showing one embodiment of a dicing/die-bonding integrated film.

FIG. 3 is a schematic cross-sectional view showing one embodiment of a semiconductor device.

FIG. 4 is a schematic cross-sectional view showing another embodiment of a semiconductor device.

FIG. 5 is a schematic cross-sectional view showing another embodiment of a semiconductor device.

FIG. 6 is a view showing a shape of a test piece used for measuring a breaking strength.

### DESCRIPTION OF EMBODIMENTS

Hereinafter, embodiments of the present disclosure will be described with appropriate reference to the drawings. However, the present disclosure is not limited to the following embodiments. In the following embodiments, the constituent elements (including steps and the like) are not essential unless otherwise specified. The sizes of the constituent elements in the drawings are conceptual, and the relative relationship between the sizes of the constituent elements is not limited to that shown in the drawings.

The same applies to numerical values and ranges thereof in the present disclosure, and the present disclosure is not limited thereto. In the present description, a numerical range indicated using “to” indicates a range including numerical values described before and after “to” as a minimum value and a maximum value, respectively. In the numerical ranges described in stages in the present description, the upper limit value or the lower limit value described in one numerical range may be replaced with the upper limit value or the lower limit value of a numerical range described in another stage. In addition, in a numerical range described in the present description, the upper limit value or the lower limit value of the numerical range may be replaced with a value shown in Examples. In addition, the upper limit value and the lower limit value described individually can be arbitrarily combined. In addition, “A or B” only needs to include either A or B, and may include both A and B. In addition, as for the materials exemplified below, one type may be used alone or two or more types may be used in combination unless otherwise specified. When a plurality of substances corresponding to each component are present in a composition, the content of each component in the composition means the total amount of the plurality of substances present in the composition unless otherwise specified.

In the present description, a (meth)acrylate means an acrylate or a methacrylate corresponding thereto. The same applies to other similar expressions such as a (meth)acryloyl group and a (meth)acrylic copolymer.

### [Film-Shaped Adhesive]

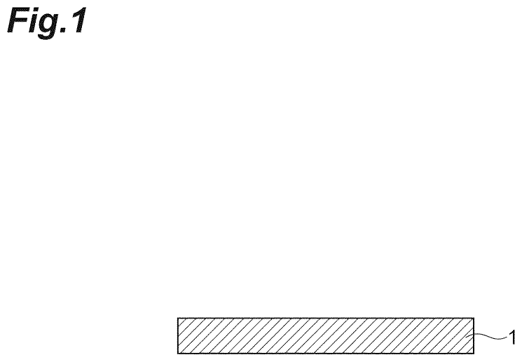

FIG. 1 is a schematic cross-sectional view showing one embodiment of a film-shaped adhesive. A film-shaped adhesive 1 shown in FIG. 1 may be thermosetting, and may be one that can be in a completely cured (C-stage) state after a curing treatment through a semi-cured (α-stage) state.

The film-shaped adhesive 1 satisfies the following conditions.
The storage modulus at 150° C. after curing under the conditions of 140° C. and 30 minutes is 80 MPa or more.
The thickness is 15 μm or less.

The storage modulus at 150° C. after the film-shaped adhesive 1 is cured under the conditions of 140° C. and 30 minutes is 80 MPa or more, and may be 85 MPa or more, 90 MPa or more, 95 MPa or more, 100 MPa or more, 105 MPa or more, 110 MPa or more, 115 MPa or more, 120 MPa or more, 125 MPa or more, or 130 MPa or more. When the storage modulus is 80 MPa or more, brittleness of a semiconductor chip due to film thinning can be compensated, and as a result, occurrence of chip cracks can be prevented. The upper limit of the storage modulus is not particularly limited, but may be, for example, 500 MPa or less, 300 MPa or less, 250 MPa or less, or 200 MPa or less.

The storage modulus at 30° C. after the film-shaped adhesive 1 is cured under the conditions of 140° C. and 30 minutes may be 2,000 MPa or less, and may be 1,800 MPa or less, 1,600 MPa or less, 1,400 MPa or less, or 1,200 MPa or less. When the storage modulus is 2,000 MPa or less, the film-shaped adhesive more easily enables film thinning, and there is a tendency that a cured product of the film-shaped adhesive can be more sufficiently prevented from becoming too hard. The lower limit of the storage modulus is not particularly limited, but may be, for example, 600 MPa or more, 700 MPa or more, 800 MPa or more, 900 MPa or more, or 1,000 MPa or more.

In the present description, the storage modulus at 150° C. after the film-shaped adhesive is cured can be measured, for example, by the following method. A plurality of film-shaped adhesives having a thickness of 5 μm are stacked to a thickness of 100 μm or more, and this is sized to a width of 4 mm×a length of 20 mm or more to prepare a sample for measurement. The prepared sample is cured under the conditions of 140° C. and 30 minutes, then the sample after curing is set in a dynamic viscoelasticity measuring device (for example, Rheogel E-4000, manufactured by UBM Co., Ltd.), and dynamic viscoelasticity is measured in a temperature-dependent measurement mode in which measurement is performed from room temperature (25° C.) to 300° C. under the conditions of a chuck distance of 20 mm, a frequency of 10 Hz, and a temperature raising rate of 3° C./minute under a tensile load. Here, the values of the storage modulus at 30° C. and 150° C. are read, and the respective values are taken as the storage moduli at 30° C. and 150° C.

The thickness of the film-shaped adhesive 1 is 15 μm or less, and may be 12 μm or less, 10 μm or less, 8 μm or less, 7 μm or less, 6 μm or less, or 5 μm or less. The lower limit of the thickness of the film-shaped adhesive is not particularly limited, but may be, for example, 1 μm or more.

The film-shaped adhesive 1 contains a thermosetting resin component (hereinafter sometimes referred to as “component (A)”) and an elastomer (hereinafter sometimes referred to as “component (B)”), and may further contain an inorganic filler (hereinafter sometimes referred to as “component (C)”). The component (A) may contain, for example, an epoxy resin (hereinafter sometimes referred to as “component (A1)”) and a phenol resin (hereinafter sometimes referred to as “component (A2)”). The content of the component (B) is 18% by mass or more with respect to the total amount of the film-shaped adhesive. The content of the component (C) is 0 to 25% by mass with respect to the total amount of the film-shaped adhesive. The film-shaped adhesive 1 may further contain a coupling agent (hereinafter sometimes referred to as “component (D)”), a curing accelerator (hereinafter sometimes referred to as “component (E)”), other components, and the like in addition to the component (A), the component (B), and the component (C). By adopting such constituent components, there is a tendency that it is easy to prepare a film-shaped adhesive satisfying the conditions of the storage modulus after curing and the thickness.

### Component (A): Thermosetting Resin Component

### Component (A1): Epoxy Resin

The component (A1) can be used without particular limitation as long as it has an epoxy group in the molecule. Examples of the component (A1) include a bisphenol A type epoxy resin; a bisphenol F type epoxy resin; a bisphenol S type epoxy resin; a phenol novolac type epoxy resin; a cresol novolac type epoxy resin; a bisphenol A novolac type epoxy resin; a bisphenol F novolac type epoxy resin; a stilbene type epoxy resin; a triazine skeleton-containing epoxy resin; a fluorene skeleton-containing epoxy resin; a triphenolmethane type epoxy resin; a biphenyl type epoxy resin; a xylylene type epoxy resin; a biphenylaralkyl type epoxy resin; a naphthalene type epoxy resin; and a diglycidyl ether compound of a polycyclic aromatic such as a polyfunctional phenol or anthracene. Among these, the component (A1) may contain a cresol novolac type epoxy resin, a bisphenol F type epoxy resin, a bisphenol A type epoxy resin, or a naphthalene type epoxy resin from the viewpoint of tackiness, flexibility, and the like of the film. Many bisphenol F type epoxy resins have a relatively low softening point and a softening point of 40° C. or lower.

The component (A1) may contain an epoxy resin having a softening point of 40° C. or lower (or an epoxy resin that is liquid at 30° C., hereinafter sometimes referred to as “component (A1a)”). The component (A1) may be a combination of the component (A1a) and an epoxy resin having a softening point higher than 40° C. (or an epoxy resin that is solid at 30° C., hereinafter sometimes referred to as “component (A1b)”). When the component (A1) contains the component (A1a), the storage modulus after curing tends to be more easily improved. In addition, when the component (A1) is a combination of the component (A1a) and the component (A1b), film thinning tends to be more easily achieved. The component (A1a) may contain, for example, a bisphenol F type epoxy resin.

In the present description, the softening point means a value measured by a ring and ball method in accordance with JIS K 7234:1986.

Examples of a commercially available product of the component (A1a) include EXA-830CRP (trade name, manufactured by DIC Corporation, liquid at 30° C.), YDF-8170C (trade name, manufactured by NIPPON STEEL Chemical & Material Co., Ltd., liquid at 30° C.), and EP-4088S (trade name, manufactured by ADEKA CORPORATION, liquid at 30° C.).

When the component (A1) is a combination of the component (A1a) and the component (A1b), the content of the component (A1a) may be 5% by mass or more, 10% by mass or more, or 15% by mass or more, and may be 70% by mass or less, 60% by mass or less, or 50% by mass or less with respect to the total amount of the component (A1). The content of the component (A1a) in the component (A1) in an adhesive composition when the film-shaped adhesive is formed may be similar to the above range.

When the component (A1) is a combination of the component (A1a) and the component (A1b), the content of the component (A1b) may be 30% by mass or more, 40% by mass or more, or 50% by mass or more, and may be 95% by mass or less, 90% by mass or less, or 85% by mass or less with respect to the total amount of the component (A1). The content of the component (A1b) in the component (A1) in the adhesive composition when the film-shaped adhesive is formed may be similar to the above range.

The epoxy equivalent of the component (A1) is not particularly limited, but may be 90 to 300 g/eq or 110 to 290 g/eq. When the epoxy equivalent of the component (A1) is in such a range, the fluidity of the adhesive composition tends to be easily ensured when the film-shaped adhesive is formed while the bulk strength of the film-shaped adhesive is maintained.

### Component (A2): Phenol Resin

The component (A2) can be a component that acts as a curing agent for the component (A1), that is, a curing agent for an epoxy resin. When the film-shaped adhesive contains the component (A2), the film-shaped adhesive is highly crosslinked, and the storage modulus after curing can be improved.

The component (A2) can be used without particular limitation as long as it has a phenolic hydroxyl group in the molecule. The component (A2) is not particularly limited as long as it has a phenolic hydroxyl group in the molecule. Examples of the component (A2) include a novolac type phenol resin obtained by condensation or co-condensation of a phenol such as phenol, cresol, resorcin, catechol, bisphenol A, bisphenol F, phenylphenol, or aminophenol and/or a naphthol such as α-naphthol, β-naphthol, or dihydroxynaphthalene with a compound having an aldehyde group such as formaldehyde in the presence of an acidic catalyst; a phenol aralkyl resin synthesized from a phenol such as allylated bisphenol A, allylated bisphenol F, allylated naphthalenediol, phenol novolac, or phenol and/or a naphthol with dimethoxyparaxylene or bis(methoxymethyl)biphenyl; a naphthol aralkyl resin; a biphenylaralkyl type phenol resin; and a phenyl aralkyl type phenol resin. Among these, the phenol resin may contain a novolac type phenol resin or a phenyl aralkyl type phenol resin.

The hydroxyl equivalent of the component (A2) may be 70 g/eq or more or 70 to 300 g/eq. When the hydroxyl equivalent of the component (A2) is 70 g/eq or more, the storage modulus tends to be further improved, and when the hydroxyl equivalent is 300 g/eq or less, it is possible to prevent defects due to foaming or generation of outgas or the like.

The softening point of the component (A2) is not particularly limited, but may be, for example, 90° C. or higher, 100° C. or higher, or 110° C. or higher. The upper limit of the softening point of the component (A2) may be, for example, 200° C. or lower.

Examples of a commercially available product of the component (A2) include PSM-4326 (trade name, manufactured by Gun Ei Chemical Industry Co., Ltd., softening point: 120° C.), J-DPP-140 (trade name, manufactured by JFE Chemical Corporation, softening point: 140° C.), and GPH-103 (trade name, manufactured by Nippon Kayaku Co., Ltd., softening point: 99 to 106° C.).

The ratio of the epoxy equivalent of the component (A1) to the hydroxyl equivalent of the component (A2) (epoxy equivalent of component (A1)/hydroxyl equivalent of component (A2)) may be 0.30/0.70 to 0.70/0.30, 0.35/0.65 to 0.65/0.35, 0.40/0.60 to 0.60/0.40, or 0.45/0.55 to 0.55/0.45 from the viewpoint of curability. When the equivalent ratio is 0.30/0.70 or more, more sufficient curability tends to be obtained. When the equivalent ratio is 0.70/0.30 or less, the viscosity can be prevented from becoming too high, and more sufficient fluidity can be obtained.

The content of the component (A1) (the sum of the component (A1a) and the component (A1b)) may be 20% by mass or more, and may be 25% by mass or more, 30% by mass or more, 35% by mass or more, 40% by mass or more, or 45% by mass or more with respect to the total amount of the film-shaped adhesive. When the content of the component (A1) is in such a range, the storage modulus after curing tends to be more easily improved. The content of the component (A1) may be 70% by mass or less, 65% by mass or less, 60% by mass or less, or 55% by mass or less with respect to the total amount of the film-shaped adhesive from the viewpoint of handleability. The content of the component (A1) (the sum of the component (A1a) and the component (A1b)) in the adhesive composition when the film-shaped adhesive is formed may be similar to the above range.

The content of the component (A2) may be 10% by mass or more, and may be 12% by mass or more, 15% by mass or more, 18% by mass or more, 20% by mass or more, or 22% by mass or more with respect to the total amount of the film-shaped adhesive. When the content of the component (A2) is in such a range, the storage modulus after curing tends to be more easily improved. The content of the component (A2) may be 35% by mass or less, 32% by mass or less, or 30% by mass or less with respect to the total amount of the film-shaped adhesive from the viewpoint of handleability. The content of the component (A2) in the adhesive composition when the film-shaped adhesive is formed may be similar to the above range.

The content of the component (A) (the sum of the component (A1) and the component (A2)) may be 40% by mass or more, and may be 45% by mass or more, 50% by mass or more, 55% by mass or more, 60% by mass or more, 65% by mass or more, or 70% by mass or more with respect to the total amount of the film-shaped adhesive. When the content of the component (A) is in such a range, the storage modulus after curing tends to be more easily improved. The content of the component (A) may be 90% by mass or less, 85% by mass or less, or 80% by mass or less with respect to the total amount of the film-shaped adhesive from the viewpoint of handleability. The content of the component (A) (the sum of the component (A1) and the component (A2)) in the adhesive composition when the film-shaped adhesive is formed may be similar to the above range.

### Component (B): Elastomer

Examples of the component (B) include an acrylic resin, a polyester resin, a polyamide resin, a polyimide resin, a silicone resin, a butadiene resin; and modified products of these resins. Examples of the component (B) include a polymer having an organopolysiloxane in a side chain. Among these, the component (B) may be an acrylic resin (acrylic rubber) containing a constituent unit derived from a (meth)acrylic acid ester as a main component because of containing less ionic impurities, being more excellent in heat resistance, being easier to ensure connection reliability of a semiconductor device, and having more excellent fluidity. The content of the constituent unit derived from the (meth)acrylic acid ester in the component (B) may be, for example, 70% by mass or more, 80% by mass or more, or 90% by mass or more with respect to the total amount of the constituent units. The acrylic resin (acrylic rubber) may contain a constituent unit derived from a (meth)acrylic acid ester having a crosslinkable functional group such as an epoxy group, an alcoholic or phenolic hydroxyl group, or a carboxyl group.

The glass transition temperature (Tg) of the component (B) may be 0 to 30° C. When the Tg of the component (B) is 0° C. or higher, the adhesive strength of the film-shaped adhesive can be further improved, and moreover, there is a tendency that the flexibility of the film-shaped adhesive can be prevented from becoming too high. When the Tg of the component (B) is 30° C. or lower, a decrease in flexibility of the film-shaped adhesive can be prevented, and the breaking strength when a thin film is formed is excellent, and also the processability tends to be excellent. The glass transition temperature (Tg) of the component (B) may be 5° C. or higher or 10° C. or higher, and may be 25° C. or lower or 20° C. or lower. Here, Tg means a value measured using a thermal differential scanning calorimeter (DSC) (for example, Thermo Plus 2 manufactured by Rigaku Corporation). The Tg of the component (B) can be adjusted within a desired range by adjusting the type and content of the constituent unit constituting the component (B) (when the component (B) is an acrylic resin (acrylic rubber), a constituent unit derived from a (meth)acrylic acid ester).

The weight average molecular weight (Mw) of the component (B) may be 100,000 or more, 300,000 or more, or 500,000 or more, and may be 3,000,000 million or less, 2,000,000 or less, or 1,000,000 or less. When the Mw of the component (B) is in such a range, the film formability, film strength, flexibility, tackiness, and the like can be appropriately controlled, and also the reflowability is excellent, and the embeddability can be improved. Here, Mw means a value obtained by measurement with gel permeation chromatography (GPC) and conversion using a standard polystyrene calibration curve. When a plurality of peaks are observed in GPC, a weight average molecular weight derived from a peak with the highest peak intensity is defined as the weight average molecular weight in the present description.

Examples of a commercially available product of the component (B) include SG-P3 and SG-80H (both manufactured by Nagase ChemteX Corporation) and KH-CT-865 (manufactured by Resonac Corporation).

The content of the component (B) is 18% by mass or more, and may be 18 to 35% by mass with respect to the total amount of the film-shaped adhesive. The content of the component (B) may be 20% by mass or more, 22% by mass or more, or 24% by mass or more with respect to the total amount of the film-shaped adhesive. When the content of the component (B) is 18% by mass or more with respect to the total amount of the film-shaped adhesive, the breaking strength when a thin film is formed is excellent, the processability is also excellent, and there is a tendency that warpage of a semiconductor device (semiconductor package) can be prevented. When the content of the component (B) is 18% by mass or more with respect to the total amount of the film-shaped adhesive, there is a tendency that the storage modulus at 30° C. after curing can be prevented from becoming too high. The content of the component (B) may be 35% by mass or less, 33% by mass or less, 30% by mass or less, or 28% by mass or less with respect to the total amount of the film-shaped adhesive. When the content of the component (B) is 35% by mass or less with respect to the total amount of the film-shaped adhesive, the storage modulus after curing tends to be more easily improved. The content of the component (B) in the adhesive composition when the film-shaped adhesive is formed may be similar to the above range.

### Component (C): Inorganic Filler

The film-shaped adhesive 1 may further contain the component (C). That is, there may be an aspect in which the film-shaped adhesive 1 contains the component (C) and an aspect in which the film-shaped adhesive 1 does not substantially contain the component (C).

Examples of the component (C) include fillers of aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whiskers, boron nitride, silica, and the like. Among these, the component (C) may be a silica filler from the viewpoint of adjusting the melt viscosity. The shape of the component (C) is not particularly limited, but may be spherical.

The average particle diameter of the component (C) may be 0.7 μm or less, and may be 0.6 μm or less, 0.5 μm or less, 0.4 μm or less, or 0.3 μm or less from the viewpoint of fluidity and storage modulus. The average particle diameter of the component (C) may be, for example, 0.01 μm or more. Here, the average particle diameter means a particle diameter at a cumulative frequency of 50% in a particle size distribution obtained by a laser diffraction/scattering method. The average particle diameter of the component (C) can also be obtained using a film-shaped adhesive containing the component (C). In this case, a residue obtained by heating the film-shaped adhesive to decompose the resin component is dispersed in a solvent to prepare a dispersion, and the average particle diameter of the component (C) can be determined from a particle size distribution obtained by applying a laser diffraction/scattering method to the dispersion.

The content of the component (C) is 0 to 25% by mass, and may be 0 to 22% by mass, 0 to 20% by mass, 0 to 17% by mass, 0 to 15% by mass, 0 to 12% by mass, 0 to 10% by mass, 0 to 7% by mass, 0 to 5% by mass, 0 to 4% by mass, 0 to 3% by mass, 0 to 2% by mass, 0 to 1% by mass, 0 to 0.5% by mass, or 0 to 0.1% by mass with respect to the total amount of the film-shaped adhesive. When the content of the component (C) is in such a range, there is a tendency for film thinning to be even more possible. In addition, when the content of the component (C) is 25% by mass or less with respect to the total amount of the film-shaped adhesive, the breaking strength when a thin film is formed is excellent, the processability is also excellent, and there is a tendency that warpage of a semiconductor device (semiconductor package) can be prevented. In one embodiment, the content of the component (C) may be 22% by mass or less, 20% by mass or less, 17% by mass or less, 15% by mass or less, 12% by mass or less, 10% by mass or less, 7% by mass or less, 5% by mass or less, 4% by mass or less, 3% by mass or less, 2% by mass or less, 1% by mass or less, 0.5% by mass or less, or 0.1% by mass or less with respect to the total amount of the film-shaped adhesive. In one embodiment, the content of the component (C) may be 0% by mass with respect to the total amount of the film-shaped adhesive. That is, in one embodiment, the film-shaped adhesive need not contain the component (C). In one embodiment, the lower limit of the component (C) may be 0% by mass or more, more than 0% by mass, 1% by mass or more, 3% by mass or more, or 5% by mass or more with respect to the total amount of the film-shaped adhesive. The content of the component (C) in the adhesive composition when the film-shaped adhesive is formed may be similar to the above range.

The component (A) and the component (B), or the component (A), the component (B), and the component (C) can be main components of the film-shaped adhesive of the present embodiment. The total content of the component (A) and the component (B) or the total content of the component (A), the component (B), and the component (C) may be, for example, 70% by mass or more, 80% by mass or more, 90% by mass or more, 95% by mass or more, 96% by mass or more, 97% by mass or more, 98% by mass or more, 99% by mass or more, 99.5% by mass or more, 99.7% by mass or more, or 99.9% by mass or more. The total content of the component (A) and the component (B) or the total content of the component (A), the component (B), and the component (C) may be, for example, 100% by mass or less, 99.9% by mass or less, 99.7% by mass or less, or 99.5% by mass or less.

### Component (D): Coupling Agent

The component (D) may be a silane coupling agent. Examples of the silane coupling agent include γ-ureidopropyltriethoxysilane, γ-mercaptopropyltrimethoxysilane, 3-phenylaminopropyltrimethoxysilane, and 3-(2-aminoethyl)aminopropyltrimethoxysilane.

### Component (E): Curing Accelerator

Examples of the component (E) include an imidazole and a derivative thereof, an organophosphorus compound, a secondary amine, a tertiary amine, and a quaternary ammonium salt. Among these, the component (E) may be an imidazole and a derivative thereof from the viewpoint of reactivity.

Examples of the imidazole include 2-methylimidazole, 1-benzyl-2-methylimidazole, 1-cyanoethyl-2-phenylimidazole, and 1-cyanoethyl-2-methylimidazole.

The component (E) may contain 2-phenylimidazole because it easily accelerates curing at a low temperature.

The film-shaped adhesive may further contain other components. Examples of the other components include a pigment, an ion scavenger, and an antioxidant.

The total content of the component (D), the component (E), and other components may be 0% by mass or more, 0.1% by mass or more, 0.3% by mass or more, or 0.5% by mass or more, and may be 30% by mass or less, 20% by mass or less, 10% by mass or less, 5% by mass or less, 4% by mass or less, 3% by mass or less, 2% by mass or less, or 1% by mass or less with respect to the total amount of the film-shaped adhesive. The total content of the component (D), the component (E), and other components in the adhesive composition when the film-shaped adhesive is formed may be similar to the above range.

The film-shaped adhesive 1 shown in FIG. 1 is obtained by molding an adhesive composition containing the component (A) and the component (B) and, if necessary, the component (C) and a component to be added into a film shape. Such a film-shaped adhesive 1 can be formed by applying the adhesive composition to a support film. In the formation of the film-shaped adhesive 1, a varnish (adhesive varnish) containing the adhesive composition and a solvent may be used. When the adhesive varnish is used, the component (A) and the component (B) and, if necessary, the component (C) and a component to be added are mixed or kneaded in a solvent to prepare an adhesive varnish, the obtained adhesive varnish is applied to a support film, and the solvent is removed by heating and drying, whereby the film-shaped adhesive 1 can be obtained.

The support film is not particularly limited as long as it withstands the heating and drying, and may be, for example, a polyester film, a polypropylene film, a polyethylene terephthalate film, a polyimide film, a polyetherimide film, a polyethylene naphthalate film, a polymethylpentene film, or the like. The support film may be a multilayer film obtained by combining two or more types, or may be surface-treated with a silicone-based or silica-based release agent or the like. The thickness of the support film may be, for example, 10 to 200 μm or 20 to 170 μm.

Mixing or kneading can be performed by using a normal disperser such as a stirrer, a crusher, a three-roll mill, or a ball mill, and appropriately combining these.

The solvent used for preparing the adhesive varnish is not limited as long as it can uniformly dissolve, knead, or disperse each component, and a conventionally known solvent can be used. Examples of such a solvent include ketone-based solvents such as acetone, methyl ethyl ketone, methyl isobutyl ketone, and cyclohexanone, dimethylformamide, dimethylacetamide, N-methylpyrrolidone, toluene, and xylene. The solvent may be methyl ethyl ketone or cyclohexanone from the viewpoint of drying speed and price.

As a method for applying the adhesive varnish to the support film, a known method can be used, and for example, a knife coating method, a roll coating method, a spray coating method, a gravure coating method, a bar coating method, a curtain coating method, or the like can be used. The heating and drying conditions are not particularly limited as long as the solvent used is sufficiently volatilized, but may be 50 to 150° C. and 1 to 30 minutes.

Since the film-shaped adhesive 1 enables film thinning, the film-shaped adhesive 1 can be suitably used in a process for producing a semiconductor device formed by stacking a plurality of semiconductor chips. In this case, the semiconductor device may be a stacked MCP or a three-dimensional NAND memory.

### [Dicing/Die-Bonding Integrated Film]

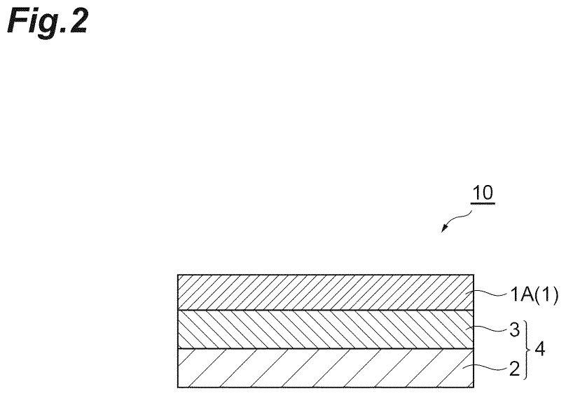

FIG. 2 is a schematic cross-sectional view showing one embodiment of a dicing/die-bonding integrated film. A dicing/die-bonding integrated film 10 shown in FIG. 2 includes a base material layer 2, a pressure-sensitive adhesive layer 3, and an adhesive layer 1A made of the film-shaped adhesive 1, in this order. A stacked body including the base material layer 2 and the pressure-sensitive adhesive layer 3 is sometimes referred to as a dicing film 4 (dicing tape). When such a dicing/die-bonding integrated film 10 is used, the lamination step on a semiconductor wafer is done only once, so that the work efficiency can be improved. The dicing/die-bonding integrated film may have a film shape, a sheet shape, a tape shape, or the like.

The dicing film 4 includes the base material layer 2 and the pressure-sensitive adhesive layer 3 provided on the base material layer 2.

Examples of the base material layer 2 include plastic films such as a polytetrafluoroethylene film, a polyethylene terephthalate film, a polyethylene film, a polypropylene film, a polymethylpentene film, and a polyimide film. These base material layers 2 may be subjected to a surface treatment such as primer application, a UV treatment, a corona discharge treatment, a polishing treatment, or an etching treatment as necessary.

The pressure-sensitive adhesive layer 3 is a layer made of a pressure-sensitive adhesive. The pressure-sensitive adhesive is not particularly limited as long as it has a sufficient adhesive strength such that the semiconductor chip does not scatter in a dicing step, and has a low adhesive strength such that the semiconductor chip is not damaged in the subsequent semiconductor chip pickup step, and those conventionally known in the field of dicing films can be used. The pressure-sensitive adhesive may be either radiation curable or non-radiation curable. The radiation may be, for example, an ultraviolet ray. The non-radiation curable pressure-sensitive adhesive is a pressure-sensitive adhesive that exhibits constant stickiness with short term pressure. On the other hand, the radiation curable pressure-sensitive adhesive is a pressure-sensitive adhesive having a property that the stickiness is lowered by irradiation with a radiation (for example, ultraviolet ray).

The thickness of the dicing film 4 (the base material layer 2 and the pressure-sensitive adhesive layer 3) may be 60 to 150 μm or 70 to 130 μm from the viewpoint of economic efficiency and film handleability.

The dicing/die-bonding integrated film 10 can be obtained, for example, by preparing the film-shaped adhesive 1 and the dicing film 4 and sticking the film-shaped adhesive 1 and the pressure-sensitive adhesive layer 3 of the dicing film 4 together. The dicing/die-bonding integrated film 10 can also be obtained, for example, by preparing the dicing film 4 and applying the adhesive composition (adhesive varnish) onto the pressure-sensitive adhesive layer 3 of the dicing film 4 in the same manner as the method for forming the film-shaped adhesive 1.

When the film-shaped adhesive 1 and the pressure-sensitive adhesive layer 3 of the dicing film 4 are stuck together, the dicing/die-bonding integrated film 10 can be formed by laminating the film-shaped adhesive 1 on the dicing film 4 under predetermined conditions (for example, at room temperature (25° C.) or in a heated state) using a roll laminator, a vacuum laminator, or the like. The dicing/die-bonding integrated film 10 may be formed using a roll laminator in a heated state because continuous production can be carried out and efficiency is excellent.

The film-shaped adhesive and the dicing/die-bonding integrated film may be used in a process for producing a semiconductor device, or may be used in a process for producing a semiconductor device formed by stacking a plurality of semiconductor chips. The film-shaped adhesive and the dicing/die-bonding integrated film may be used in a process for producing a semiconductor device including obtaining a semiconductor chip with an adhesive piece by sticking the film-shaped adhesive or the adhesive layer of the dicing/die-bonding integrated film to a semiconductor wafer or an already singulated semiconductor chip, followed by cutting with a rotary blade or a laser, or by stretching, and bonding the semiconductor chip with an adhesive piece onto a support member or a semiconductor chip via the adhesive piece.

The film-shaped adhesive is also suitably used as an adhesive for bonding semiconductor chips in a stacked MCP (for example, a three-dimensional NAND memory) which is a semiconductor device formed by stacking a plurality of semiconductor chips.

The film-shaped adhesive can also be used as, for example, a protective sheet for protecting the back surface of a semiconductor chip of a flip-chip semiconductor device, a sealing sheet for sealing the space between the front surface of a semiconductor chip of a flip-chip semiconductor device and an adherend, or the like.

Hereinafter, a semiconductor device produced using the film-shaped adhesive and the dicing/die-bonding integrated film will be specifically described with reference to the drawings. In recent years, semiconductor devices having various structures have been proposed, and the application of the film-shaped adhesive and the dicing/die-bonding integrated film of the present embodiment is not limited to the semiconductor device having a structure described below.

### [Semiconductor Device]

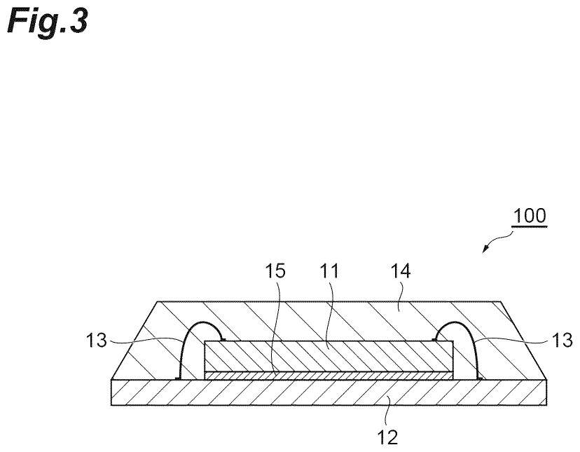

FIG. 3 is a schematic cross-sectional view showing one embodiment of a semiconductor device. A semiconductor device 100 shown in FIG. 3 includes a semiconductor chip 11 (first semiconductor chip), a support member 12 mounted with the semiconductor chip 11, and a bonding member 15. The bonding member 15 is provided between the semiconductor chip 11 and the support member 12, and bonds the semiconductor chip 11 to the support member 12. The bonding member 15 is a cured product of the adhesive composition (a cured product of the film-shaped adhesive). A connection terminal (not shown) of the semiconductor chip 11 is electrically connected to an external connection terminal (not shown) via a bonding wire 13, and sealed with a sealing material 14.

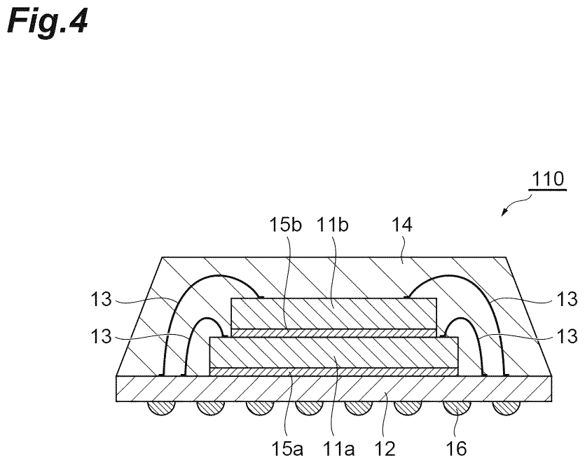

FIG. 4 is a schematic cross-sectional view showing another embodiment of a semiconductor device. In a semiconductor device 110 shown in FIG. 4, a first-stage semiconductor chip 11a (a first semiconductor chip) is bonded to a support member 12 on which a terminal 16 is formed by a bonding member 15a (a cured product of an adhesive composition (a cured product of a film-shaped adhesive)), and a second-stage semiconductor chip 11b (a second semiconductor chip) is further bonded onto the first-stage semiconductor chip 11a by a bonding member 15b (a cured product of an adhesive composition (a cured product of a film-shaped adhesive)). Connection terminals (not shown) of the first-stage semiconductor chip 11a and the second-stage semiconductor chip 11b are electrically connected to an external connection terminal via a bonding wire 13, and sealed with a sealing material 14. It can also be said that the semiconductor device 110 shown in FIG. 4 further includes another semiconductor chip (11b) stacked on the surface of the semiconductor chip (11a) in the semiconductor device 100 shown in FIG. 3.

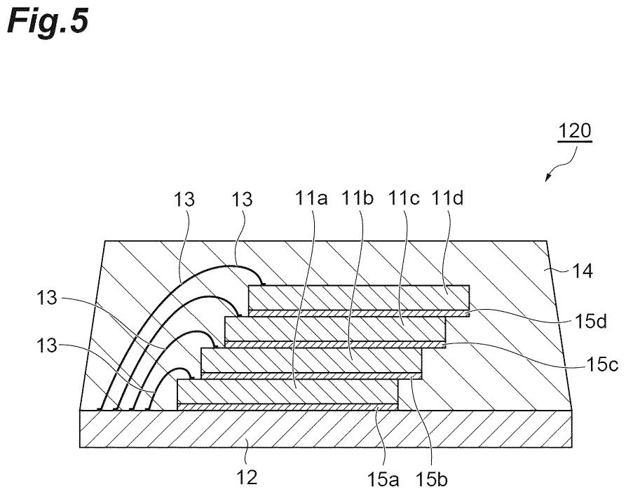

FIG. 5 is a schematic cross-sectional view showing another embodiment of a semiconductor device. A semiconductor device 120 shown in FIG. 5 includes a support member 12 and semiconductor chips 11a (first semiconductor chip), 11b (second semiconductor chip), 11c (third semiconductor chip), and 11d (fourth semiconductor chip) stacked on the support member 12. The four semiconductor chips 11a, 11b, 11c, and 11d are stacked at positions shifted from each other in the lateral direction (direction orthogonal to the stacking direction) for connection to connection terminals (not shown) formed on the surface of the support member 12 (see FIG. 5). The semiconductor chip 11a is bonded to the support member 12 by a bonding member 15a (a cured product of an adhesive composition (a cured product of a film-shaped adhesive)), and bonding members 15b, 15c, and 15d (cured products of adhesive compositions (cured products of film-shaped adhesives)) are interposed between the three semiconductor chips 11b, 11c, and 11d, respectively. It can also be said that the semiconductor device 120 shown in FIG. 5 further includes other semiconductor chips (11b, 11c, and 11d) stacked on the surface of the semiconductor chip (11a) in the semiconductor device 100 shown in FIG. 3.

Although the semiconductor device (semiconductor package) has been described in detail in the embodiments of the present disclosure, the present disclosure is not limited to the above embodiments. For example, FIG. 5 illustrates a semiconductor device in which four semiconductor chips are stacked, but the number of semiconductor chips to be stacked is not limited thereto. In addition, in FIG. 5, a semiconductor device of an aspect in which semiconductor chips are stacked at positions shifted from each other in the lateral direction (direction orthogonal to the stacking direction) is illustrated, but may be a semiconductor device of an aspect in which semiconductor chips are stacked at positions not shifted from each other in the lateral direction (direction orthogonal to the stacking direction).

### [Method for Producing Semiconductor Device]

The semiconductor devices (semiconductor packages) shown in FIGS. 3, 4, and 5 can be obtained by a method including interposing the film-shaped adhesive between a semiconductor chip (first semiconductor chip) and a support member or between a semiconductor chip (first semiconductor chip) and a semiconductor chip (second semiconductor chip), and bonding the semiconductor chip (first semiconductor chip) and the support member, or bonding the semiconductor chip (first semiconductor chip) and the semiconductor chip (second semiconductor chip). More specifically, the semiconductor devices can be obtained by interposing the film-shaped adhesive between a semiconductor chip and a support member or between a semiconductor chip (first semiconductor chip) and a semiconductor chip (second semiconductor chip), bonding these by thermocompression bonding, and then undergoing a thermal curing step, a wire bonding step, a sealing step with a sealing material, a heating and melting step including reflow with solder, and the like as necessary.

A method for interposing the film-shaped adhesive between a semiconductor chip (first semiconductor chip) and a support member or between a semiconductor chip (first semiconductor chip) and a semiconductor chip (second semiconductor chip) may be a method in which a semiconductor chip with an adhesive piece is prepared in advance and then stuck to a support member or another semiconductor chip as described later.

Next, an embodiment of a method for producing a semiconductor device using the dicing/die-bonding integrated film shown in FIG. 2 will be described. The method for producing a semiconductor device using the dicing/die-bonding integrated film is not limited to the method for producing a semiconductor device described below.

The semiconductor device can be obtained, for example, by a method including sticking a semiconductor wafer to the adhesive layer of the dicing/die-bonding integrated film (lamination step), preparing a plurality of singulated semiconductor chips with an adhesive piece by cutting the semiconductor wafer with the adhesive layer stuck thereto (dicing step), and bonding, as the semiconductor chip with an adhesive piece, a first semiconductor chip with an adhesive piece having a first semiconductor chip and a first adhesive piece to a support member via the first adhesive piece (bonding the semiconductor chip with an adhesive piece to the support member via the adhesive piece) (first bonding step).

The method for producing a semiconductor device may further include bonding, as the semiconductor chip with an adhesive piece, a second semiconductor chip with an adhesive piece having a second semiconductor chip and a second adhesive piece to a surface of the first semiconductor chip in the first semiconductor chip with an adhesive piece bonded to the support member via the second adhesive piece (bonding another semiconductor chip with an adhesive piece to a surface of the semiconductor chip bonded to the support member via the adhesive piece included in the another semiconductor chip with an adhesive piece) (second bonding step).

The lamination step is pressure-bonding a semiconductor wafer to the adhesive layer 1A in the dicing/die-bonding integrated film 10 to bond and hold the semiconductor wafer to stick the semiconductor wafer thereto. This step may be performed while pressing by a pressing means such as a pressure-bonding roller.

Examples of the semiconductor wafer include single crystal silicon, polycrystalline silicon, various ceramics, and compound semiconductors such as gallium arsenide.

The dicing step is dicing a semiconductor wafer. As a result, the semiconductor wafer can be cut into a predetermined size, and a plurality of singulated semiconductor chips with an adhesive piece can be produced. The dicing can be performed, for example, from the circuit surface side of the semiconductor wafer according to a conventional method. In addition, in this step, for example, a method called full cut in which a cut is provided up to the dicing film, a method in which a half cut is provided in the semiconductor wafer, and the semiconductor wafer is divided by being cooled and pulled, a method in which cutting is performed with a laser, or the like can be adopted. A dicing device used in this step is not particularly limited, and a conventionally known one can be used.

The semiconductor chip includes, for example, a circuit layer and a semiconductor layer (for example, single crystal silicon, polycrystalline silicon, various ceramics, or a compound semiconductor such as gallium arsenide). Examples of the semiconductor chip include an integrated circuit (IC). Examples of the support member include a lead frame such as a 42-alloy lead frame or a copper lead frame; a plastic film of a polyimide resin, an epoxy resin, or the like; a modified plastic film obtained by impregnating a base material such as a glass nonwoven fabric with a plastic such as a polyimide resin or an epoxy resin and curing the plastic; and a ceramic such as alumina.

The method for producing a semiconductor device may include a pickup step as necessary. The pickup step is picking up the semiconductor chip with an adhesive piece in order to peel the semiconductor chip with an adhesive piece adhesively fixed to the dicing/die-bonding integrated film. A pickup method is not particularly limited, and various conventionally known methods can be adopted.

Examples of such a method include a method in which individual semiconductor chips with an adhesive piece are pushed up with a needle from the dicing/die-bonding integrated film side, and the pushed-up semiconductor chips with an adhesive piece are picked up with a pickup device.

Here, when the pressure-sensitive adhesive layer is radiation (for example, ultraviolet ray) curable, the pickup can be performed after the pressure-sensitive adhesive layer is irradiated with a radiation. As a result, the adhesive strength of the pressure-sensitive adhesive layer to the adhesive piece decreases, and the semiconductor chip with an adhesive piece is easily peeled. As a result, it is possible to perform pickup without damaging the semiconductor chip with an adhesive piece.

The first bonding step is bonding the first semiconductor chip with an adhesive piece formed by dicing to a support member for mounting the semiconductor chip via the first adhesive piece. The method for producing a semiconductor device may include bonding the second semiconductor chip with an adhesive piece to the surface of the semiconductor chip bonded to the support member via the second adhesive piece (second bonding step) as necessary. Any bonding can be performed by pressure-bonding. The pressure-bonding conditions are not particularly limited, and can be appropriately set as necessary. The pressure-bonding conditions may be, for example, a temperature of 80 to 160° C., a load of 5 to 15 N, and a time of 1 to 10 seconds. As the support member, support members similar to those described above can be exemplified.

The method for producing a semiconductor device may include further thermally curing an adhesive piece (the first adhesive piece in the first semiconductor chip with an adhesive piece and the second adhesive piece in the second semiconductor chip with an adhesive piece) or a film-shaped adhesive (thermal curing step) as necessary. Stronger adhesive fixing can be achieved by further thermally curing the adhesive pieces that bond the semiconductor chip (first semiconductor chip) and the support member, and the semiconductor chip (first semiconductor chip) and the semiconductor chip (second semiconductor chip) (the first adhesive piece in the first semiconductor chip with an adhesive piece and the second adhesive piece in the second semiconductor chip with an adhesive piece). When thermal curing is performed, curing may be performed by simultaneously applying pressure. The heating temperature in this step can be appropriately changed according to the constituent components of the adhesive piece. The heating temperature may be, for example, 60 to 200° C. or 100 to 180° C. The temperature or the pressure may be changed stepwise. The heating time may be, for example, 1 to 120 minutes or 15 to 60 minutes.

The method for producing a semiconductor device may include electrically connecting the first semiconductor chip and the second semiconductor chip to the support member with a bonding wire, more specifically, electrically connecting an electrode pad on the semiconductor chip to a tip of a terminal portion (inner lead) of the support member with a bonding wire (wire bonding step) as necessary.

As the bonding wire, for example, a gold wire, an aluminum wire, a copper wire, or the like is used. The temperature when the wire bonding is performed may be in a range of 80 to 250° C. or 80 to 220° C. The heating time may be several seconds to several minutes. The wire bonding may be performed using both vibration energy by ultrasonic waves and pressure-bonding energy by applied pressure in a state of being heated within the above temperature range.

The method for producing a semiconductor device may include sealing the semiconductor chip with a sealing material (sealing step) as necessary. This step is performed to protect the semiconductor chip mounted on the support member or the bonding wire. This step can be performed by molding a resin for sealing (sealing resin) with a mold. The sealing resin may be, for example, an epoxy-based resin. The support member and the residue are embedded by heat and pressure at the time of sealing, and peeling due to bubbles at the bonding interface can be prevented.

The method for producing a semiconductor device may include completely curing the sealing resin that is insufficiently cured in the sealing step (post-curing step) as necessary. Even when the adhesive piece is not thermally cured in the sealing step, in this step, the adhesive piece is thermally cured together with the curing of the sealing resin, so that adhesive fixing can be achieved. The heating temperature in this step can be appropriately set according to the type of the sealing resin, and may be, for example, in a range of 165 to 185° C., and the heating time may be about 0.5 to 8 hours.

The method for producing a semiconductor device may include heating the semiconductor chip bonded to the support member or the semiconductor chip using a reflow furnace (heating and melting step) as necessary. In this step, the semiconductor device sealed with a resin may be surface-mounted on the support member. Examples of a surface mounting method include reflow soldering in which solder is supplied in advance onto a printed wiring board, then heated and melted by hot air or the like to perform soldering. Examples of the heating method include hot air reflow and infrared reflow. In addition, the heating method may be one that heats the entire area or one that heats a local area. The heating temperature may be, for example, in a range of 240 to 280° C.

### EXAMPLES

Hereinafter, the present disclosure will be specifically described based on examples, but the present disclosure is not limited thereto.

### [Preparation of Film-Shaped Adhesive]

### Examples 1 to 5 and Comparative Examples 1 to 4

### <Preparation of Adhesive Varnish>

Cyclohexanone was added to a mixture containing the component (A) (the component (A1) and the component (A2)) and the component (C) according to the components and the contents (unit: parts by mass) shown in Table 1, followed by stirring and mixing. To this, according to the components and the contents (unit: parts by mass) shown in Table 1, the component (B) was added, followed by stirring, and further the component (D) and the component (E) were added, followed by stirring until the respective components were homogeneous to prepare an adhesive varnish. The components shown in Table 1 denote the following materials, and the numerical values shown in Table 1 denote parts by mass of the components (solid contents) excluding the solvent and the like.

### Component (A): Thermosetting Resin Component

### Component (A1): Epoxy Resin

(Ala-1) EXA830-CRP (trade name, manufactured by DIC Corporation, bisphenol F type epoxy resin, epoxy equivalent: 155 to 163 g/eq, softening point: 40° C. or lower, liquid at 30° C.)
(A1b-1) N-500P-10 (trade name, manufactured by DIC Corporation, o-cresol novolac type epoxy resin, epoxy equivalent: 204 g/eq, softening point: 75 to 85° C., solid at 30° C.)
(A1b-2) HP-4710 (trade name, manufactured by DIC Corporation, naphthalene type epoxy resin, epoxy equivalent: 170 g/eq, softening point: 95° C., solid at 30° C.)

### Component (A2): Phenol Resin

(A2-1) PSM-4326 (trade name, manufactured by Gun Ei Chemical Industry Co., Ltd., novolac type phenol resin, hydroxyl equivalent: 105 g/eq, softening point: 120° C.)

### Component (B): Elastomer

(B-1) SG-P3 (trade name, manufactured by Nagase ChemteX Corporation, acrylic rubber, weight average molecular weight: 800,000, Tg: 12° C.)

### Component (C): Inorganic Filler

(C-1) Silica filler dispersion (manufactured by CIK NanoTek Corporation, silica filler, average particle diameter: 0.10 μm)
(C-2) SC2050-HLG (trade name, manufactured by Admatechs Co., Ltd., silica filler dispersion, average particle diameter: 0.50 μm)

### Component (D): Coupling Agent

(D-1) Z-6119 (trade name, manufactured by Dow Toray Co., Ltd., γ-ureidopropyltriethoxysilane)
(D-2) A-189 (trade name, manufactured by Nippon Unicar Company Limited, γ-mercaptopropyltrimethoxysilane)

### Component (E): Curing Accelerator

(E-1) 2PZ (trade name, manufactured by SHIKOKU CHEMICALS CORPORATION, 2-phenylimidazole)
(E-2) 2PZ-CN (trade name, manufactured by SHIKOKU CHEMICALS CORPORATION, 1-cyanoethyl-2-phenylimidazole)

### <Preparation of Film-Shaped Adhesive>

The adhesive varnish prepared was filtered through a 100 mesh filter and then subjected to vacuum defoaming. A 38 μm-thick polyethylene terephthalate (PET) film subjected to a release treatment was prepared as a support film, and the adhesive varnish after vacuum defoaming was applied onto the PET film. The applied adhesive varnish was heated and dried at 90° C. for 5 minutes and then at 140° C. for 5 minutes to obtain film-shaped adhesives of Examples 1 to 5 and Comparative Examples 1 to 4 in the B-stage state. In the film-shaped adhesives of Examples 1 to 5 and Comparative Examples 1 to 4, the thickness of the film-shaped adhesive was adjusted to 5 μm by the application amount of the adhesive varnish.

### [Evaluation of Film-Shaped Adhesive]

### <Measurement of Storage Modulus>

The storage modulus after curing was measured using the film-shaped adhesives of Examples 1 to 5 and Comparative Examples 1 to 4. The storage modulus after curing was measured by the following method. That is, a plurality of film-shaped adhesives having a thickness of 5 μm were stacked to a thickness of 100 μm or more, and this was sized to a width of 4 mm×a length of 20 mm or more to prepare a sample for measurement. The prepared sample was cured under the conditions of 140° C. and 30 minutes, then the sample after curing was set in a dynamic viscoelasticity measuring device (Rheogel E-4000, manufactured by UBM Co., Ltd.), and dynamic viscoelasticity was measured in a temperature-dependent measurement mode in which measurement is performed from room temperature (25° C.) to 300° C. under the conditions of a chuck distance of 20 mm, a frequency of 10 Hz, and a temperature raising rate of 3° C./minute under a tensile load, and the values of the storage modulus at 30° C. and 150° C. were read and the values were taken as the storage moduli at 30° C. and 150° C., respectively. The results are shown in Table 1. The storage modulus at 150° C. indicates that the larger the numerical value (for example, 80 MPa or more) is, the more the brittleness of the semiconductor chip due to film thinning can be compensated, and as a result, occurrence of chip cracks can be prevented. The storage modulus at 30° C. indicates that the smaller the numerical value (for example, 2,000 MPa or less) is, the more easily the film-shaped adhesive enables film thinning, and the more sufficiently a cured product of the film-shaped adhesive can be prevented from becoming too hard.

### <Measurement of Breaking Strength>

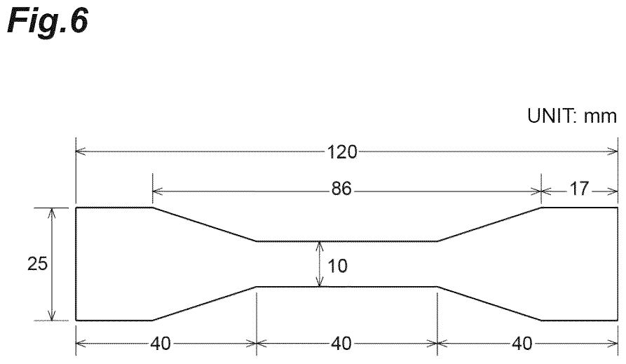

The breaking strength at 25° C. of each of the film-shaped adhesives of Examples 1 to 5 and Comparative Examples 1 to 4 was measured using a tensile tester (RTF-1250-HS-PL, A&D Company, Limited). More specifically, a test piece having a shape shown in FIG. 6 was prepared using the film-shaped adhesive in the B-stage state. A tensile test was performed by holding both ends of the prepared test piece by the tester. The tensile test was performed in an environment of 25° C., and the tensile speed was set to 100 mm/min. The breaking strength was calculated by the following formula from the average thickness (0.005 mm (5 μm)) and width (10 mm) of the test piece before the test and the maximum load (N) until the test piece was broken. The results are shown in Table 1. The numerical values shown in Table 1 are values (unit: N/10 mm) converted into loads when the average thickness of the test piece before the test is 5 μm. The breaking strength indicates that the larger the numerical value (for example, 0.7 N/10 mm or more) is, the better the processability is when a thin film is formed.

Breaking strength (MPa)=Maximum load (N) until test piece is broken/(Average thickness (mm) of test piece×width (mm))

### <Evaluation of Warpage of Semiconductor Device (Semiconductor Package)>

### (Preparation of Dicing/Die-Bonding Integrated Film)

A dicing film (trade name: 6363-45, manufactured by Resonac Corporation) having a base material and a pressure-sensitive adhesive layer was prepared, and the pressure-sensitive adhesive layer of the dicing film was stuck to each of the film-shaped adhesives of Examples 1 to 5 and Comparative Examples 1 to 4 with a rubber roll to produce dicing/die-bonding integrated films of Examples 1 to 5 and Comparative Examples 1 to 4 including the base material, the pressure-sensitive adhesive layer, and an adhesive layer (film-shaped adhesive) in this order.

### (Preparation of Evaluation Sample)

Evaluation samples were prepared using the dicing/die-bonding integrated films of Examples 1 to 5 and Comparative Examples 1 to 4. An evaluation sample for evaluating warpage was prepared as follows. A semiconductor wafer having a thickness of 40 μm was prepared, and the dicing/die-bonding integrated film on the film-shaped adhesive side was laminated on the semiconductor wafer at a stage temperature of 70° C. to prepare a dicing sample. The obtained dicing sample was cut using a full auto dicer DFD-6362 (manufactured by DISCO Corporation). The cutting was performed by a single cut method using one blade, and ZH05-SD4000-N1-70-EE (manufactured by DISCO Corporation) was used. Cutting conditions were set as follows: blade rotation speed: 40,000 rpm, cutting speed: 50 mm/sec, and chip size: 10 mm×6 mm. The cutting was performed so that a cut of about 20 μm was made in the dicing film. Then, the pressure-sensitive adhesive layer made of an ultraviolet curable pressure-sensitive adhesive was irradiated with an ultraviolet ray to cure the pressure-sensitive adhesive layer, and a semiconductor chip with an adhesive piece was picked up. Subsequently, the adhesive piece of the semiconductor chip with an adhesive piece was pressure-bonded to an organic substrate with a solder resist having a thickness of 90 μm×a width of 240 mm×a length of 74 mm under the conditions of a temperature of 130° C., a load of 10 N, and a time of 1 second to prepare evaluation samples of Examples 1 to 5 and Comparative Examples 1 to 4. In the evaluation sample, 60 semiconductor chips in the first stage were arranged side by side in 15 rows and 4 columns, and subsequently 60 semiconductor chips in the second stage were arranged on the surface of each semiconductor chip in the first stage.

### (Evaluation of Warpage of Semiconductor Device (Semiconductor Package))

Warpage of a semiconductor device (semiconductor package) was evaluated using the evaluation samples of Examples 1 to 5 and Comparative Examples 1 to 4. Each evaluation sample was placed in an oven, heated from 35° C. to 140° C. at a temperature raising rate of 3° C./min, and heated at 140° C. for 30 minutes. The evaluation sample after the heat treatment was taken out from the pressure oven, and the amount of warpage of the semiconductor device (semiconductor package) was measured. More specifically, the evaluation sample after the heat treatment was placed on a flat surface with the semiconductor chip side facing downward, a digimatic indicator ID-H0530 (manufactured by Mitutoyo Corporation) was used, five points of the upper left, upper right, center, lower left, and lower right of the evaluation sample after the heat treatment placed on the flat surface were set as measurement points, and a difference between the maximum value and the minimum value of the measurement results was determined as the amount of warpage. A case where the amount of warpage was 3.0 mm or less was evaluated as “A” on the assumption that the amount of warpage was sufficiently reduced, and a case where the amount of warpage was more than 3.0 mm was evaluated as “B”. The results are shown in Table 1.

TABLE 1

| | | | | | | | | Comp. | Comp. | Comp. | Comp. |
|---|---|---|---|---|---|---|---|---|---|---|---|
| | | | Exam. 1 | Exam. 2 | Exam. 3 | Exam. 4 | Exam. 5 | Exam. 1 | Exam. 2 | Exam. 3 | Exam. 4 |
| (A) | (A1) | (Ala-1) | 14.2 | 10.0 | 12.6 | 15.6 | 13.0 | 16.2 | 14.6 | — | 11.0 |
| | | (A1b-1) | 14.0 | 39.7 | 24.8 | — | — | 5.1 | 22.0 | 11.0 | — |
| | | (Alb-2) | 24.0 | — | 0.9 | 23.2 | 19.3 | — | 3.5 | — | 14.3 |
| | (A2) | (A2-1) | 25.6 | 24.6 | 23.0 | 20.6 | 17.1 | 13.4 | 24.3 | 10.0 | 13.4 |

| | | | | | | | | | | |
|---|---|---|---|---|---|---|---|---|---|---|
| (B) | (B-1) | 21.6 | 25.0 | 33.0 | 30.0 | 30.0 | 15.0 | 35.0 | 70.0 | 16.0 |
| (C) | (C-1) | — | — | 5.0 | 10.0 | 20.0 | — | — | — | 35.0 |
| | (C-2) | — | — | — | — | — | 49.9 | — | 8.6 | — |
| (D) | (D-1) | 0.26 | 0.26 | 0.26 | 0.26 | 0.26 | 0.26 | 0.26 | 0.26 | 0.09 |
| | (D-2) | 0.13 | 0.13 | 0.13 | 0.13 | 0.13 | 0.13 | 0.13 | 0.13 | 0.18 |
| (E) | (E-1) | 0.23 | 0.27 | 0.26 | 0.22 | 0.17 | — | 0.23 | — | 0.08 |
| | (E-2) | — | — | — | — | — | 0.05 | — | 0.02 | — |
| Storage | MPa, 150° C. | 140 | 220 | 101 | 120 | 140 | 172 | 76 | 2 | 107 |
| modulus | MPa, 30° C. | 1100 | 1150 | 1600 | 1100 | 1200 | 4600 | 1400 | 650 | 2300 |
| Breaking | N/10 mm, | 0.8 | 1.1 | 1.4 | 0.9 | 1.0 | 0.2 | 1.7 | 2.1 | 0.5 |
| strength | 25° C. | | | | | | | | | |

| | | | | | | | | | |
|---|---|---|---|---|---|---|---|---|---|
| Evaluation of warpage of | A | A | A | A | A | B | A | A | B |
| semiconductor device | | | | | | | | | |

As shown in Table 1, the film-shaped adhesives of Examples 1 to 5 were excellent in both storage modulus at 150° C. and breaking strength, whereas the film-shaped adhesives of Comparative Examples 1 to 4 were insufficient in at least one of the storage modulus at 150° C. and the breaking strength. From these results, it was verified that the film-shaped adhesive of the present disclosure is excellent in processability when a thin film is formed, and can prevent the occurrence of chip cracks.

### REFERENCE SIGNS LIST

1: film-shaped adhesive, 1A: adhesive layer, 2: base material layer, 3: pressure-sensitive adhesive layer, 4: dicing film, 10: dicing/die-bonding integrated film, 11, 11a, 11b, 11c, 11d: semiconductor chip, 12: support member, 13: bonding wire, 14: sealing material, 15, 15a, 15b, 15c, 15d: bonding member, 16: terminal, 100, 110, 120: semiconductor device

1. A film-shaped adhesive, comprising: a thermosetting resin component; and an elastomer, and optionally further comprising an inorganic filler, wherein
a content of the elastomer is 18% by mass or more with respect to a total amount of the film-shaped adhesive,
a content of the inorganic filler is 0 to 25% by mass with respect to the total amount of the film-shaped adhesive,
a storage modulus at 150° C. of a cured product obtained when the film-shaped adhesive is cured at 140° C. for 30 minutes is 80 MPa or more, and
a thickness of the film-shaped adhesive is 15 μm or less.

2. The film-shaped adhesive according to claim 1, wherein
a content of the elastomer is 18 to 35% by mass with respect to the total amount of the film-shaped adhesive.

3. The film-shaped adhesive according to claim 1, wherein
a content of the inorganic filler is 0 to 3% by mass with respect to the total amount of the film-shaped adhesive.

4. The film-shaped adhesive according to claim 1, wherein
a storage modulus at 30° C. of a cured product obtained when the film-shaped adhesive is cured under conditions of 140° C. and 30 minutes is 2,000 MPa or less.

5. The film-shaped adhesive according to claim 1, wherein
the thermosetting resin component comprises an epoxy resin and a phenol resin.

6. The film-shaped adhesive according to claim 1, wherein
a glass transition temperature of the elastomer is 0 to 30° C.

7. The film-shaped adhesive according to claim 1, wherein
the film-shaped adhesive is used in a process for producing a semiconductor device formed by stacking a plurality of semiconductor chips.

8. The film-shaped adhesive according to claim 7, wherein
the semiconductor device is a three-dimensional NAND memory.

9. A dicing/die-bonding integrated film, comprising:
a base material layer; a pressure-sensitive adhesive layer; and an adhesive layer made of the film-shaped adhesive according to claim 1, wherein
the pressure-sensitive adhesive layer is located between the base material layer and the adhesive layer made of the film-shaped adhesive.

10. A semiconductor device, comprising:
a first semiconductor chip;
a support member mounted with the first semiconductor chip; and
a cured product of the film-shaped adhesive according to claim 1, the cured product being provided between the first semiconductor chip and the support member and bonding the first semiconductor chip to the support member.

11. The semiconductor device according to claim 10, further comprising
a second semiconductor chip different from the first semiconductor chip, the second semiconductor chip being stacked on a surface of the first semiconductor chip.

12. A method for producing a semiconductor device, the method comprising:
sticking the adhesive layer of the dicing/die-bonding integrated film according to claim 9 to a semiconductor wafer;
preparing a plurality of singulated semiconductor chips with an adhesive piece by cutting the semiconductor wafer with the adhesive layer stuck thereto; and
bonding, as the semiconductor chip with an adhesive piece, a first semiconductor chip with an adhesive piece having a first semiconductor chip and a first adhesive piece to a support member via the adhesive piece.

13. The method for producing a semiconductor device according to claim 12, further comprising:
bonding, as the semiconductor chip with an adhesive piece, a second semiconductor chip with an adhesive piece having a second semiconductor chip and a second adhesive piece to a surface of the first semiconductor chip in the first semiconductor chip with an adhesive piece bonded to the support member via the second adhesive piece.

14. The film-shaped adhesive according to claim 3, wherein
a storage modulus at 30° C. of a cured product obtained when the film-shaped adhesive is cured under conditions of 140° C. and 30 minutes is 2,000 MPa or less.

15. The film-shaped adhesive according to claim 3, wherein
the thermosetting resin component comprises an epoxy resin and a phenol resin.

16. The film-shaped adhesive according to claim 3, wherein
a glass transition temperature of the elastomer is 0 to 30° C.

17. A dicing/die-bonding integrated film, comprising:
a base material layer; a pressure-sensitive adhesive layer; and an adhesive layer made of the film-shaped adhesive according to claim 3, wherein
the pressure-sensitive adhesive layer is located between the base material layer and the adhesive layer made of the film-shaped adhesive.

18. A film-shaped adhesive, comprising: a thermosetting resin component; and an elastomer, wherein
a content of the elastomer is 18% by mass or more with respect to a total amount of the film-shaped adhesive,
a storage modulus at 150° C. of a cured product obtained when the film-shaped adhesive is cured at 140° C. for 30 minutes is 80 MPa or more, and
a thickness of the film-shaped adhesive is 15 μm or less.

19. The film-shaped adhesive according to claim 18, wherein the film-shaped adhesive further comprises an inorganic filler having a content that is less than or equal to 25% by mass with respect to the total amount of the film-shaped adhesive.

20. The film-shaped adhesive according to claim 18, wherein the film-shaped adhesive comprises a negligible amount, or none, of an inorganic filler.
